(19) United States
(12) Patent Application Publication
(10) Pub. No.: US 2026/0080933 A1
(43) Pub. Date: Mar. 19, 2026

(54) SYSTEMS AND METHODS FOR BOOSTING A WORDLINE

(71) Applicants: Advanced Micro Devices, Inc., Santa Clara, CA (US); ATI Technologies ULC, Markham (CA)

(72) Inventors: Russell Schreiber, Austin, TX (US); Sahilpreet Singh, Markham (CA); Prateek Sahney, Markham (CA); Ilango Jeyasubramanian, Austin, TX (US)

(73) Assignees: Advanced Micro Devices, Inc., Santa Clara, CA (US); ATI Technologies ULC, Markham, ON (CA)

(21) Appl. No.: 18/887,679

(22) Filed: Sep. 17, 2024

(51) Int. Cl. G11C 11/408; G11C 5/14; G11C 11/4076

(52) U.S. Cl. CPC G11C 11/4085; G11C 5/145; G11C 11/4076

(57) ABSTRACT

A method can include driving, at a first end of a first memory bank, a first metal layer that includes a wordline of the first memory bank. The method can also include boosting, based on an output of the first metal layer at a second end of the first memory bank, a voltage of the first metal layer. Various other methods and systems are also disclosed.

### BACKGROUND

In computing, a memory can correspond to an electronic holding place for the instructions and/or data a computer needs to reach quickly. Examples of memory can include, without limitation, cache memory, main memory, and secondary memory. Different types of memory can be different in various aspects, such as numbers of channels or links, different storage capacities, and/or different rates. One type of memory, referred to as random access memory (RAM), is a form of electronic computer memory that can be read and changed in any order, typically used to store working data and machine code. RAM and other types of memory can be composed of memory cells, which are electronic circuits that store one bit of binary information such as a logical one (e.g., high voltage) or a logical zero (e.g., low voltage). These memory cells can be arranged in columns and rows to form memory banks.

A wordline can correspond to one or more rows (e.g., eight bits) of a memory cell. For example, a wordline can be an array of rows of memory cells in RAM, used with a bitline to generate the address of each cell. In some examples, a wordline can be a horizontal strip of polysilicon that connects to a transistor's (cell's) control gate, and a bitline can be connected to a cell's drain. Different voltage combinations applied to the wordline and bitline can define a read, erase, or write operation on the cell.

In various examples, wordlines can implemented in various types of RAM, such as dynamic random access memory (DRAM) or static random access memory (SRAM). For example, a single piece of DRAM can be composed of a large two dimensional array of cells containing ones or zeros that are connected by bitlines and wordlines. Each individual cell can be accessed by utilizing the intersection of a specific wordline and bitline and reading from or storing to the cell at this address. Similarly, SRAM arrays can be arranged in several rows and columns of storage bit-cells called bit-lines (BL and BL') and word-lines (WL) to control data access and storage. The bit-cells can be bi-stable flip-flops that include a number (e.g., four to eleven) of transistors with pull-up (PU), pull-down (PD), and pass-gate (PG) networks.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for boosting a wordline.

FIG. 2 is a block diagram of example wordline drive circuitry and wordline booster circuitry.

FIG. 3 is a block diagram of example wordline drive circuitry and wordline booster circuitry that is controlled based on a signal.

FIG. 4 is a block diagram of example memory banks including wordline drive circuitry and wordline booster circuitry.

FIG. 5 is a graphical illustration of example boosting of a voltage of a wordline during a wordline operation.

FIG. 6 is a block diagram comparing example memory banks with and without wordline booster circuitry.

FIG. 7 is a block diagram illustrating an example memory device including multiple memory banks including wordline drive circuitry and wordline booster circuitry.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for boosting a wordline. For example, by driving, at a first end of a first memory bank, a first metal layer that includes a wordline of the first memory bank and boosting, based on an output of the first metal layer at a second end of the first memory bank, a voltage of the first metal layer, the disclosed systems and methods can achieve numerous benefits. Example benefits achieved by the disclosed systems and methods can include an increase in the capacity (e.g., length) of a wordline (e.g., a row of a memory bank) without decrease in performance or change of voltage range. Also, increasing the capacity of a memory bank in this way can result in a more efficient use of area in semiconductor devices.

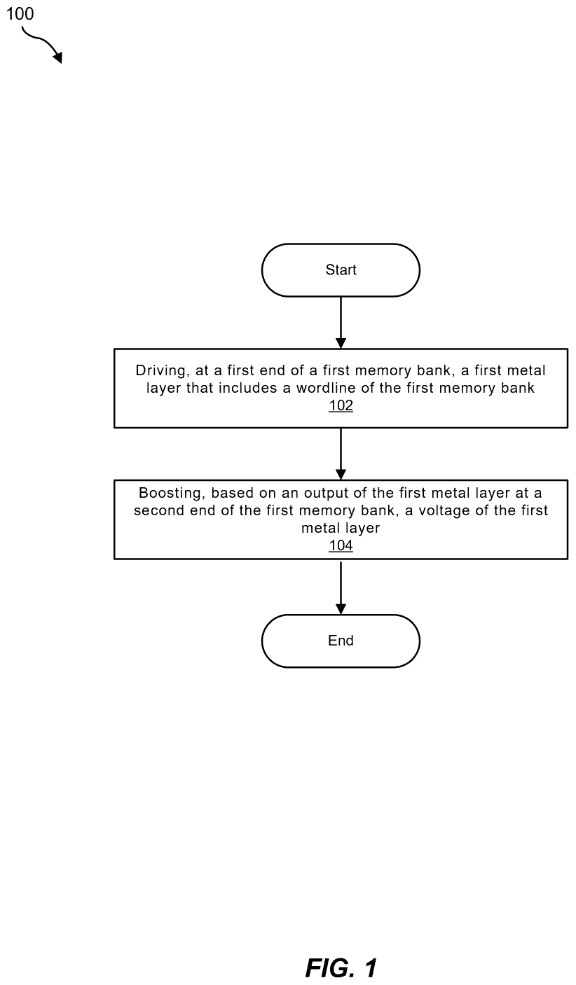

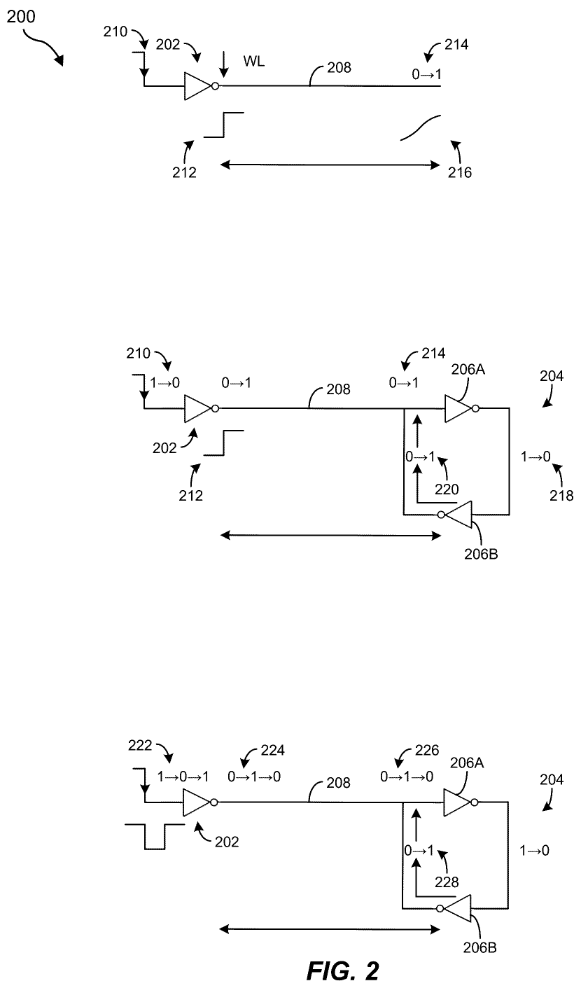

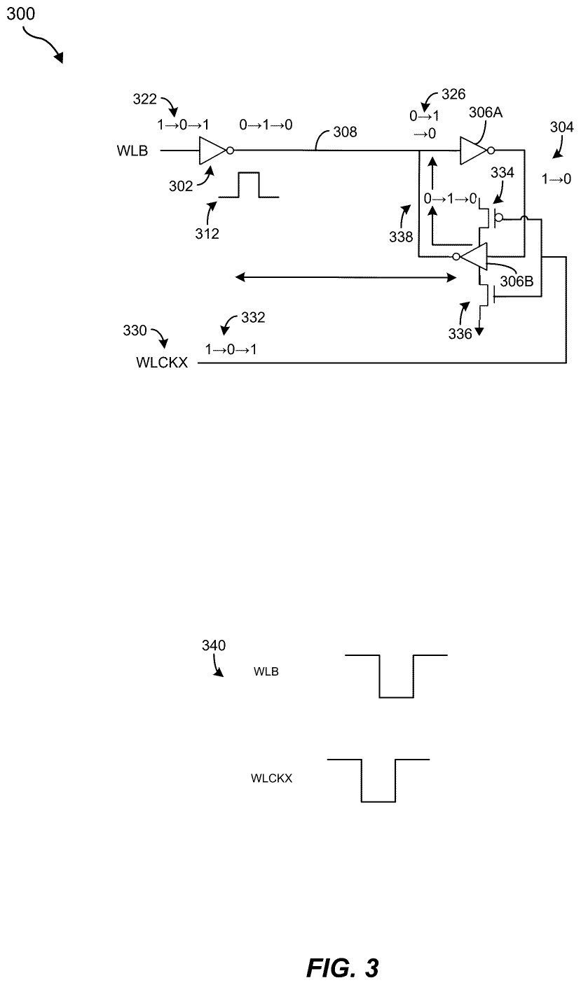

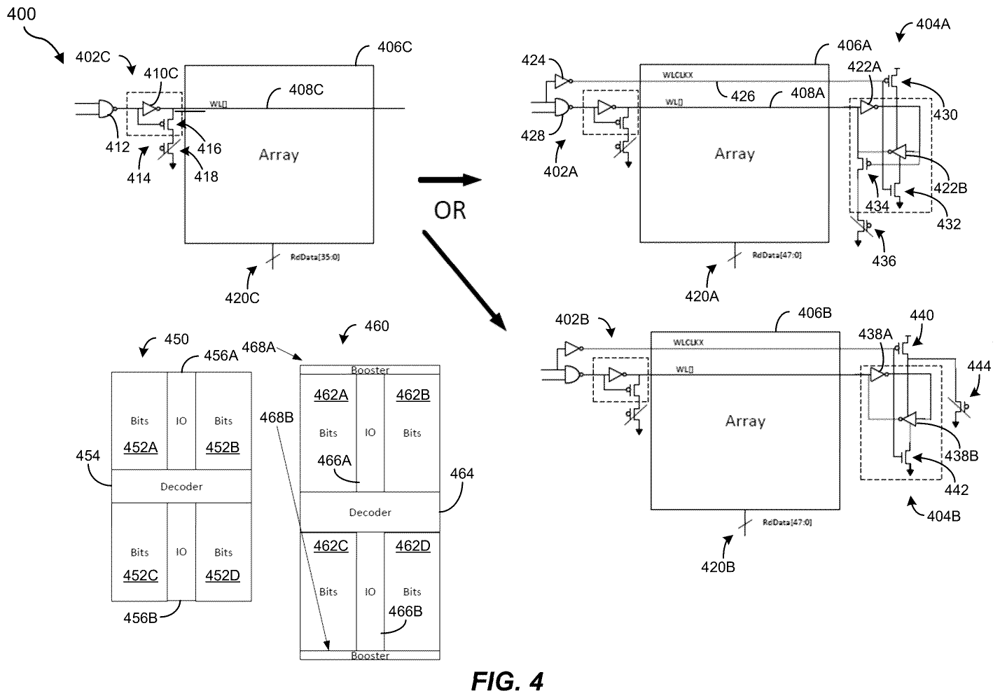

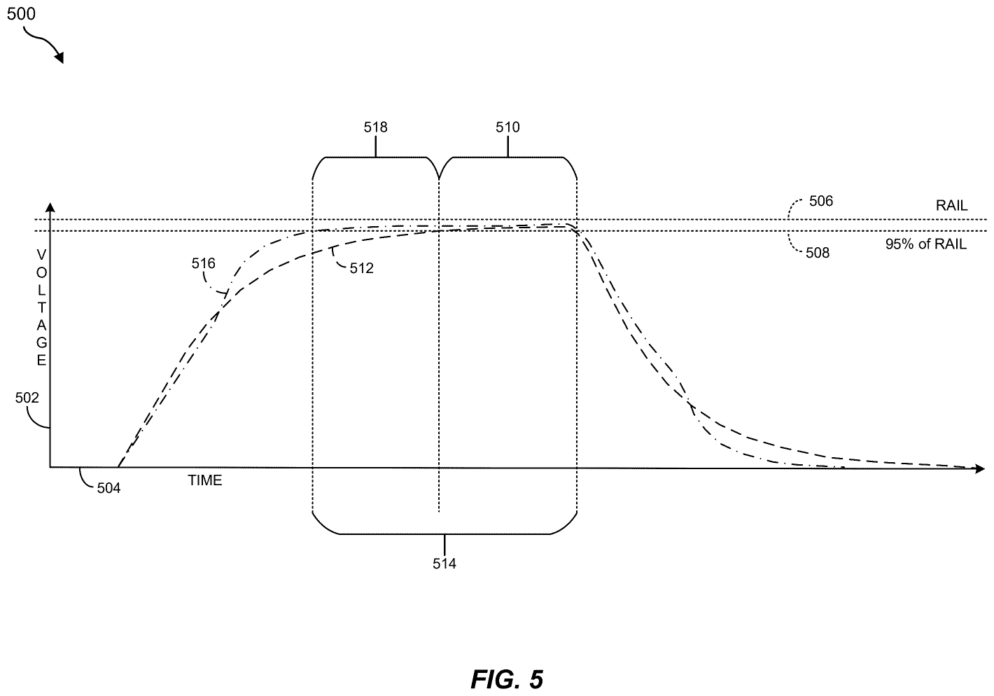

The following will provide, with reference to FIG. 1, detailed descriptions of example methods for boosting a wordline. Detailed descriptions of example wordline drive circuitry and wordline booster circuitry are also provided herein with reference to FIGS. 2 and 3. Additionally, detailed descriptions of example memory banks including wordline drive circuitry and wordline booster circuitry are provided herein with reference to FIGS. 4, 6, and 7. Further, detailed descriptions of example boosting of a voltage of a wordline during a wordline operation are provided herein with reference to FIG. 5.

In one example, a device can include a first wordline drive circuit configured to drive, at a first end of a first memory bank, a first metal layer of the first memory bank that includes a wordline and a wordline booster circuit configured to boost, based on an output of the first metal layer at a second end of the first memory bank, a voltage of the first metal layer.

Another example can be the previously described example device, further including a transistor configured to control the boosting of the voltage based on an output of a second metal layer of the first memory bank.

Another example can be any of the previously described example devices, further including a second wordline drive circuit configured to drive, based on the output of the second metal layer, a first metal layer of a second memory bank that includes the wordline.

Another example can be any of the previously described example devices, wherein the first memory bank has a larger capacity than the second memory bank.

Another example can be any of the previously described example devices, wherein the second metal layer is a higher metal layer compared to the first metal layer.

Another example can be any of the previously described example devices, further including an underdrive circuit configured to decrease an amount by which the voltage of the first metal layer is boosted.

Another example can be any of the previously described example devices, wherein, during a wordline operation, a duration for which the voltage exceeds ninety-five percent of rail is longer than sixty picoseconds.

In one example, a system can include a first memory bank including a first metal layer that includes a wordline, a first wordline drive circuit configured to drive, at a first end of the first memory bank, the first metal layer, and a first wordline booster circuit configured to boost a voltage of the first metal layer based on an output of the first metal layer at a second end of the first memory bank.

Another example can be the previously described example system, further including a transistor configured to control the boosting of the voltage based on an output of a second metal layer of the first memory bank.

Another example can be any of the previously described example systems, further including a second wordline drive circuit configured to drive, based on the output of the second metal layer, a first metal layer of a second memory bank, wherein the first metal layer of the second memory bank includes the wordline and the first memory bank has a larger capacity than the second memory bank.

Another example can be any of the previously described example systems, wherein the second metal layer is a higher metal layer of the first memory bank compared to the first metal layer.

Another example can be any of the previously described example systems, further including an underdrive circuit configured to decrease an amount by which the voltage of the first metal layer is boosted.

Another example can be any of the previously described example systems, wherein, during a wordline operation, a duration for which the voltage exceeds ninety-five percent of rail is longer than sixty picoseconds.

In one example, a method can include driving, at a first end of a first memory bank, a first metal layer that includes a wordline of the first memory bank and boosting, based on an output of the first metal layer at a second end of the first memory bank, a voltage of the first metal layer.

Another example can be the previously described example method, further including controlling the boosting of the voltage based on an output of a second metal layer of the first memory bank.

Another example can be any of the previously described example methods, further including driving, based on the output of the second metal layer, a first metal layer of a second memory bank that includes the wordline.

Another example can be any of the previously described example systems, wherein the first memory bank has a larger capacity than the second memory bank.

Another example can be any of the previously described example systems, wherein the second metal layer is a higher metal layer of the first memory bank compared to the first metal layer.

Another example can be any of the previously described example systems, further including employing an underdrive to decrease an amount by which the voltage of the first metal layer is boosted.

Another example can be any of the previously described example systems, further including maintaining for longer than sixty picoseconds, during a wordline operation, a duration for which the voltage exceeds ninety-five percent of rail.

FIG. 1 is a flow diagram of an example method 100 for boosting a wordline (e.g., of a wordline array and/or memory bank). For example, method 100 can be performed by digital and/or analog circuitry that can include various circuit elements that can be arranged in various combinations. Example types of circuit elements that can perform one or more portions of method 100 can include communication media, such as metal traces, metal layers of semiconductor devices, a data communications bus, etc.

A data communications bus can be a communication system that transfers data between components inside a computer or between computers. For example, a data communication bus can be digital or analog and can entail digital only protocols without the need for physical (PHY) and/or analog components. Thus, a data communication bus can include all related hardware components (e.g., wire, optical fiber, etc.) and/or software, including communication protocols.

Early computer buses were parallel electrical wires with multiple hardware connections, but the term is now used for any physical arrangement that provides the same logical function as a parallel electrical busbar. Modern computer buses can use both parallel and bit serial connections and can be wired in either a multidrop (electrical parallel) or daisy chain topology, or connected by switched hubs, as in the case of Universal Serial Bus (USB). Example types of communication buses and corresponding bus protocols can include Peripheral Component Interconnect Express (PCIe), Universal Chiplet Interconnect Express (UCIe), Bunch of Wires (BoW), USB, Controller Area Network (CAN), Local Interconnect Network (LIN), Ethernet, Transmission control Protocol (TCP), Internet Protocol (IP), Avionics Full-Duplex Switched Ethernet (AFDX), Ethernet Consist Network (ECN), etc.

Additional types of circuit elements that can perform one or more portions of method 100 can include one or more driving transistors and/or logic transistors. For example, driving transistors (e.g., metal-oxide-semiconductor field effect-transistors (MOSFETS) or any other type of transistor) can amplify a voltage and/or current of an input signal (e.g., from a sensor, transducer, processing unit, etc.). Additionally, logic transistors can function as logic gates (e.g., AND gates, NAND gates, OR gates, NOT gates (e.g., inverters), etc.) and be composed of junction transistors or any other type of transistor. In this context, a transistor can correspond to a miniature semiconductor that regulates or controls current or voltage flow in addition to amplifying and generating these electrical signals and acting as a switch/gate for them. Typically, transistors can include three layers, or terminals, of a semiconductor material, each of which can carry a current.

Driving transistors and/or logic transistors can be implemented in various ways to boost a wordline. Wordline driving circuitry, for example, can include one or more driving transistors configured as NOT gates (e.g., inverters) and/or NAND gates. In an example, the wordline driving circuitry can receive one or more signals, such as a clock signal, and an output of the wordline driving circuitry can be connected to a metal layer at one end of a memory bank. Also, wordline booster circuitry can include one or more inverters (e.g., two inverters connected in series). In an example, the wordline booster circuitry can receive an output from the metal layer at another end of the memory bank and an output of the wordline booster circuitry can feed back a boosted voltage into the output of the metal layer at the other end of the memory bank (e.g., opposite the end at which the output of the wordline driving circuitry is connected to the metal layer). Additionally, underdrive circuitry can include one or more transistors that can direct to drain a portion of the voltage output from the wordline driving circuitry and/or the voltage input to and/or output from the wordline booster circuitry. In an example, separate wordline underdrive circuits can be provided to the wordline driving circuitry and the wordline booster circuitry and can lower an amount by which the wordline is driven at one end of the memory bank and boosted at the other. Such wordline overdrive circuits can avoid overdriving the wordline voltage, thus assisting with bitcell read stability.

In some implementations, the wordline driving circuitry can receive a signal (e.g., the clock signal) after it is gated by a NAND gate, and the ungated clock signal can be received by another inverter having its output connected to another metal layer of the memory bank that does not include the wordline. An output terminal of the other inverter can be connected to this other metal layer at the same end of the memory bank at which the wordline driving circuitry is connected. In an example, this other metal layer can be a higher metal layer than the one to which the wordline driving circuitry is connected. With this ungated clock signal driven on the other metal layer, one or more additional transistors (e.g., two additional transistors that can control the voltage) of the wordline booster circuitry can receive the ungated clock signal from the other metal layer at the other end of the memory bank and control (e.g., enable and disable) the wordline booster circuitry based on the ungated clock signal.

As illustrated in FIG. 1 at step 102, one or more of the systems described herein can drive a metal layer. For example, wordline driving circuitry can drive, at a first end of a first memory bank, a first metal layer that includes a wordline of the first memory bank.

Driving of a metal layer can be performed by a transistor (e.g., an inverter). For example, driving the metal layer can include amplifying a voltage and/or current of an input signal (e.g., from a sensor, transducer, processing unit, etc.). In this context, an inverter can amplify a clock signal and output the amplified clock signal to a metal layer of a semiconductor device (e.g., a memory). For example, an inverter can amplify a gated clock signal received from a NAND gate and output the amplified, gated clock signal to the metal layer.

Semiconductor devices typically include metal layers that can correspond to wiring (e.g., metal traces) in and/or on a wafer and/or chip. For example, this wiring can interconnect individual devices (e.g., transistors, capacitors, resistors, etc.) of an integrated circuit. In some examples, a metal layer can include copper and/or aluminum.

A memory bank can correspond to a computer device or component in which information is stored to be retrieved as needed. For example, a memory bank can include a memory controller along with physical organization of hardware memory slots. In a typical synchronous dynamic random-access memory (SDRAM) or double data rate SDRAM (DDR SDRAM), a bank can include multiple rows and columns of storage units and can be spread out across several chips. In some implementations, only one bank may be accessed during a single read or write operation. Thus, a number of bits in a column or a row, per bank and per chip, can equal a memory bus width in bits (e.g., single channel). The capacity and physical area of a bank can further be determined by the number of bits in a column and a row, per chip, multiplied by the number of chips in a bank.

Method 100 can perform step 102 in a variety of ways. For example, the wordline driving circuitry can, at step 102, receive a clock signal and generate a voltage on the first metal layer at the first end of the memory bank based on the clock signal. In some of these implementations, a transistor (e.g., an inverter) of the wordline driving circuitry can, at step 102, receive a gated clock signal from a gate (e.g., a NAND gate) and generate a voltage on the first metal layer at the first end of the memory bank based on the gated clock signal. Additionally, the wordline booster circuitry can, at step 102, employ an underdrive to decrease the voltage generated on the first metal layer, thus avoiding overdriving the voltage. In some implementations, the wordline driving circuitry can employ the underdrive at an output of the wordline driving circuitry.

As shown in FIG. 1 at step 104, one or more of the systems described herein can boost a voltage. For example, wordline booster circuitry can boost, based on an output of the first metal layer at a second end of the first memory bank, a voltage of the first metal layer.

Boosting a voltage of a metal layer can be performed by one or more transistors (e.g., two inverters connected in series). For example, boosting the voltage can include amplifying a voltage of an input signal (e.g., received from an end of the metal layer opposite one from which it is driven). In this context, the voltage can be amplified and fed back into the metal layer (e.g., at the end of the metal layer opposite one from which it is driven). In this context, the voltage of the metal layer can be boosted by driving it from two ends (e.g., opposite ends).

Method 100 can perform step 104 in a variety of ways. For example, the wordline booster circuitry can, at step 102, control the boosting of the voltage based on an output of a second metal layer of the first memory bank. Also, the wordline booster circuitry can, at step 102, drive, based on the output of the second metal layer, a first metal layer of a second memory bank that includes the wordline. In some of these examples, the first memory bank can have a larger capacity than the second memory bank. Additionally, in some implementations, the second metal layer can be a higher metal layer of the first memory bank compared to the first metal layer. Further, the wordline booster circuitry can, at step 102, employ an underdrive to decrease an amount by which the voltage of the first metal layer is boosted. In various implementations, the wordline booster circuitry can, at step 102, employ the underdrive at an input to the wordline booster circuitry or an output from the wordline booster circuitry. Together, wordline driving circuitry and wordline booster circuitry can at steps 102 and 104, maintain, for longer than sixty picoseconds, a duration for which the voltage exceeds ninety-five percent of rail during a wordline operation.

A rail voltage can correspond to a specific direct current voltage in a system. For example, a rail can refer to an electrically conductive medium (e.g., power line, voltage network, etc.) that can supply a load (e.g., an electronic circuit) with a steady voltage (e.g., a voltage that does not change beyond operational parameters for a circuit). Examples of rail voltages can include an output of a direct current power supply, an output of a voltage source network in a circuit, etc. Common rail voltages for various circuits and systems can include 3.5V, 5V, 12V, etc.

FIG. 2 illustrates example circuitry 200 that includes examples of wordline drive circuitry 202 and wordline booster circuitry 204. For example, wordline drive circuitry 202 can include an inverter and wordline booster circuitry 204 can include two or more inverters 206A and 206B connected in series. Additionally, an output of the wordline drive circuitry 202 can be connected to a wordline 208 at one end of the wordline 208 and both an input and an output of the wordline booster circuitry can be connected to the wordline 208 at the other end of the wordline 208. As shown at 210, when an input to the wordline drive circuitry 202 goes low, an output from the inverter of the wordline booster circuitry can go high as at 212 and an output at the other end of the wordline 208 can also go high as at 214. However, the output at the other end of a long wordline (e.g., fifty or sixty micrometers) can be skewed as at 216. Thus, the length of the wordline 208 can be limited in order to reduce the skew and consequent timing issues.

Instead of reducing the length of the wordline 208, wordline line booster circuitry 204 can reduce the skew at the output of the wordline 208 by feeding back a high voltage into the output of the wordline 208. For example, when, as shown at 210, an input to the wordline drive circuitry 202 goes low, an output from the inverter of the wordline drive circuitry 202 can go high as at 212 and the output at the other end of the wordline 208 can also go low as at 214. Thus, the input to the first inverter 206A of the wordline booster circuitry 204 can go low, and the output from the inverter 206A can go high as at 218. This output at 218 can serve as the input to the second inverter 206B of the wordline booster circuitry 204, an output of which can go high as at 220. This output from the second inverter 206B can feedback into the output of the wordline 208 and, consequently, the input to the wordline booster circuitry 204. Feeding the output of the wordline booster circuitry 204 back into the output of the wordline 208 can reduce the skew, permitting lengthening of the wordline and, consequently, a memory bank that includes the wordline.

An issue remains regarding resetting of the wordline 208. For example, when the input to the wordline drive circuitry 202 again goes high as at 222, the output of the wordline drive circuitry can go low as at 224, as can the output at the other end of the wordline as at 226. However, the wordline booster circuitry 204 can still be pushing a high output as at 228, thus conflicting with the output of the wordline 208 by boosting the voltage during a reset of the wordline 208.

FIG. 3 illustrates example circuitry 300 that includes wordline drive circuitry 302 and wordline booster circuitry 304 that is controlled based on a signal 330 in order to avoid boosting the voltage of a wordline 308 during a reset. For example, when an input signal (e.g., a clock signal that can be referred to as wordline bar (WLB)) to the wordline drive circuitry 302 goes from low to high as at 322, an output from the wordline drive circuitry 302 can go from high to low as at 312, as can an output from the wordline 308 at the other end of the wordline 308 as at 326. An output of a first inverter 306A connected to the output of wordline 308 can still be pushing a low voltage to a second inverter 306B, but second inverter 306B can be enabled and disabled based on the signal 330.

As shown in FIG. 3, signal 330 (e.g., a clock signal referred to as wordline clock x (WLCX)) can go from low to high as at 332 in a similar manner as the input to the wordline drive circuitry 302. For example, the input signal to the wordline drive circuitry 302 and the signal 330 can have the same amplitude and period, but can be asynchronous, as shown at 340, to ensure that signal 330 rises from zero to one and falls from one to zero before the input signal to the wordline drive circuitry 302 does so. A transistor 334 (e.g., a PMOS transistor) connected to a terminal of the second inverter 306B of wordline booster circuitry 304 and another transistor 336 (e.g., an NMOS transistor) connected to another terminal of the second inverter 306B of the wordline booster circuitry 304 can both receive signal 330. The transistor 334 can be configured to enable the second inverter 306B of the wordline booster circuitry 304 based on the signal 330 (e.g., when the signal 330 goes high). With the other transistor 336 connected to drain, this other transistor can be configured to disable the second inverter 306B of the wordline booster circuitry 304 based on the signal 330 (e.g., when the signal 330 goes low). In this way, signal 330 can enable and disable the boosting of the voltage of the wordline 308 by the wordline booster circuitry 304 in response to the signal 330. As a result, the output of the second inverter 306B can go from high to low as at 338 and avoid conflicting with the output of the wordline 308 during a reset of the voltage of the wordline 308.

FIG. 4 illustrates example memory banks 400 including wordline drive circuitry 402A-402C and wordline booster circuitry 404A and 404B. Example memory bank 406C can have a metal layer that includes a wordline 408C and wordline drive circuitry 402C that drives the metal layer at one end. The wordline drive circuitry 402C can include a transistor 410C (e.g., an inverter) that receives a gated clock signal from a gate 412 (e.g., a NAND gate) that receives an ungated clock signal. The wordline drive circuitry can also include an underdrive 414 connected in parallel with the transistor 410C. This underdrive 414 can include a transistor 416 (e.g., a PMOS transistor) and another transistor 418 (e.g., another PMOS transistor) connected in series. As shown, the transistor 416 can have one of its terminals connected at the output of the transistor 410C, another of its terminals connected to the gated clock signal, and yet another of its terminals connected to a terminal of the transistor 418. The transistor 418 can have another of its terminals connected to ground and be set at yet another of its terminals to short the output of the transistor 410C at a DC peak value that is less than a voltage of the wordline 408C. However, without a booster circuit at the other end of the wordline 408C, data 420C read from memory bank 406C can be limited to thirty-five units of data (e.g., bits).

As shown in FIG. 4, example memory bank 406A can have wordline drive circuitry 402A connected to one end of a metal layer that includes wordline 408A. Wordline drive circuitry 402A can include features that are the same as or similar to those of wordline drive circuitry 402C. Additionally, example memory bank 406A can have wordline booster circuitry 404A that includes a pair of transistors 422A and 422B (e.g., inverters) connected in series, with transistor 422A connected to receive an input from the metal layer at the other end of the wordline 408A. Transistors 422A and 422B can be configured to feedback a voltage into the metal layer at the other end of the wordline 408A.

As shown in FIG. 4, an additional transistor 424 (e.g., an inverter) can receive an ungated clock signal and its output can be connected to another metal layer 426 of memory bank 406A at the same end as the wordline drive circuitry 402A. This other metal layer 426 can be any metal layer that is available (e.g., a metal layer that does not include the wordline 408A). For example, this other metal layer 426 can be a higher metal layer compared to the one that includes the wordline 408A. A gate 428 that gates the clock signal provided to the wordline drive circuitry 402A can delay the clock signal, causing the ungated clock signal and the gated clock signal to be asynchronous. As a result, the ungated clock signal can rise and fall before the gated clock signal rises and falls as shown in FIG. 3 at 340.

As shown in FIG. 4, an output from the other metal layer 426 at the other end of the memory bank 406A can be connected to one or more terminals of one or more additional transistors 430 and 432 (e.g., two additional transistors that can control the voltage) of the wordline booster circuitry 404A can receive the ungated clock signal from the other metal layer 426 at the other end of the memory bank and control (e.g., enable and disable) the wordline booster circuitry 404A based on the ungated clock signal. Transistors 430 and 432 can be the same or similar to transistors 334 and 336 of FIG. 3. For example, transistor 430 (e.g., a PMOS transistor) connected to a terminal of the second transistor 422B of wordline booster circuitry 404A and transistor 432 (e.g., an NMOS transistor) connected to another terminal of the second transistor 422B of the wordline booster circuitry 404A can both receive the inverted, ungated clock signal from the other metal layer 426. The transistor 430 can be configured to enable the second transistor 422B of the wordline booster circuitry 404A based on the inverted, ungated clock signal (e.g., when the signal goes high). With the other transistor 432 connected to drain, this other transistor 432 can be configured to disable the second transistor 422B of the wordline booster circuitry 404A based on the inverted, ungated clock signal (e.g., when the signal goes low). In this way, the inverted, ungated clock signal can enable and disable the boosting of the voltage of the wordline 408A by the wordline booster circuitry 404A in response to the inverted, ungated clock signal. As a result, the output of the second transistor 422B can go from high to low and avoid conflicting with the output of the wordline 408A during a reset of the voltage of the wordline 408A.

As shown in FIG. 4, the wordline booster circuitry 404A can also include an underdrive connected in parallel with the transistor 422B. This underdrive can include a transistor 434 (e.g., a PMOS transistor) and another transistor 436 (e.g., another PMOS transistor) connected in series. As shown, the transistor 434 can have one of its terminals connected at the input of the transistor 422B, another of its terminals connected to the output of transistor 422B, and yet another of its terminals connected to a terminal of the transistor 436. The transistor 436 can have another of its terminals connected to ground and be set at yet another of its terminals to short the output of the transistor 436 at a DC peak value that is less than a voltage of the wordline 408A. With wordline booster circuitry 404A connected at the other end of the wordline 408A, an amount of data 420A read from memory bank 406A can be increased compared to an amount of data 420C read from memory bank 406C. For example, the amount of data can increase by more than thirty-four percent (e.g., from thirty-five units of data to forty-seven units of data).

As shown in FIG. 4, example memory bank 406B can have wordline drive circuitry 402B and wordline booster circuitry 404B connected and arranged in a manner that is the same or similar to memory bank 406A, wordline drive circuitry 402A, and wordline booster circuitry 404A as previously described. For example, wordline booster circuitry 404B can include a pair of transistors 438A and 438B (e.g., inverters) connected in series. Additionally, wordline booster circuitry 404B can include one or more additional transistors 430 and 432 (e.g., two additional transistors that can control the voltage). Transistors 438A, 438B, 440, and 442 can be the same or similar to transistors 422A, 422B, 430, and 432 as previously described. However, wordline booster circuitry 404B can include an underdrive that includes a transistor 444 (e.g., a PMOS transistor) having one of its terminals connected between terminals of transistors 440 and 442 that are connected to one another. The transistor 444 can have another of its terminals connected to ground and be set at yet another of its terminals to short the connection between terminals of transistors 440 and 442 at a DC peak value that is less than a voltage of a wordline of memory bank 406B. The underdrive of wordline booster circuitry 404B can include less transistors than an underdrive of wordline booster circuitry 404A, reducing costs and/or area. With wordline booster circuitry 404B connected at the other end of the wordline of memory bank 406B, an amount of data 420B read from memory bank 406B can be increased compared to an amount of data 420C read from memory bank 406C. For example, the amount of data can increase by more than thirty-four percent (e.g., from thirty-five units of data to forty-seven units of data).

As shown in FIG. 4, memory device 450 can include memory banks 452A-452D that have features detailed above with reference to memory bank 406C. Memory device 450 can also include a decoder 454 that includes one or more instances of wordline drive circuitry 402C and is arranged between memory banks 452A and 452C and between memory banks 452B and 452D. Memory device 450 can additionally include input output circuitry 456A and 456B arranged between memory banks 452A and 452B and between memory banks 452C and 452D.

As shown in FIG. 4, memory device 460 can include memory banks 462A-462D that have features detailed above with reference to memory banks 406A and/or 406B. Memory device 460 can also have a decoder 464 that includes one or more instances of wordline drive circuitry 402A and/or 402B. Memory device 460 can additionally include input output circuitry 466A and 466B arranged between memory banks 462A and 462B and between memory banks 462C and 462D. Memory device 460 can further include wordline booster circuitry 468A and 468B that can include one or more instances of wordline booster circuitry 404A and/or 404B. Wordline booster circuitry 468A and 468B can be arranged and connected at ends of memory banks 462A-462D opposite decoder 464. With wordline booster circuitry 468A and 468B, a physical length and storage capacity of memory banks 462A-462D of memory device 460 can be increased compared to a physical length and storage capacity of memory banks 452A-452D of memory device 450. For example, the physical length and capacity of memory banks 462A-462D can be increased by more than thirty-four percent.

FIG. 5 illustrates that example boosting 500 of a voltage of a wordline during a wordline operation (e.g., an access, read, write, etc.) can increase a duration at which the voltage driving the wordline exceeds ninety-five percent of rail. In this context, a wordline can be reliably operated upon (e.g., accessed, written, read, etc.) when the voltage exceeds ninety-five percent of rail. Thus increasing, during a wordline operation, the duration at which the voltage driving the wordline exceeds ninety-five percent of rail can increase an amount of time to operate upon the data stored in the wordline. Accordingly, the length of the wordline and the amount of data that can be stored in the wordline can be increased without decreasing performance or causing a change of voltage range. Also, increasing the capacity of a memory bank in this way can result in a more efficient use of area in a semiconductor device.

As shown in FIG. 5, increasing wordline voltage 502 can be represented by an abscissa and increasing time 504 can be represented by an ordinate axis. Additionally, a rail voltage 506 can correspond to a voltage supplied to a circuit that includes a wordline and a ninety-five percent of rail voltage 508 can indicate a voltage above which the wordline can be reliably operated upon (e.g., accessed, written, read, etc.). Also, without wordline booster circuitry, a duration 510 for which a voltage 512 of the wordline exceeds ninety-five percent of rail voltage 508 can be shorter than sixty picoseconds. With wordline booster circuitry, however, a duration 514 for which a voltage 516 of the wordline exceeds ninety-five percent of rail voltage 508 can be longer than sixty picoseconds. For example, the duration 514 with wordline booster circuitry can include an additional duration 518 of fifty-five picoseconds. Thus, the addition of additional duration 518 can nearly double the duration 514 with wordline booster circuitry (e.g., an increase of more than ninety-two percent) compared to the duration 510 without wordline booster circuitry.

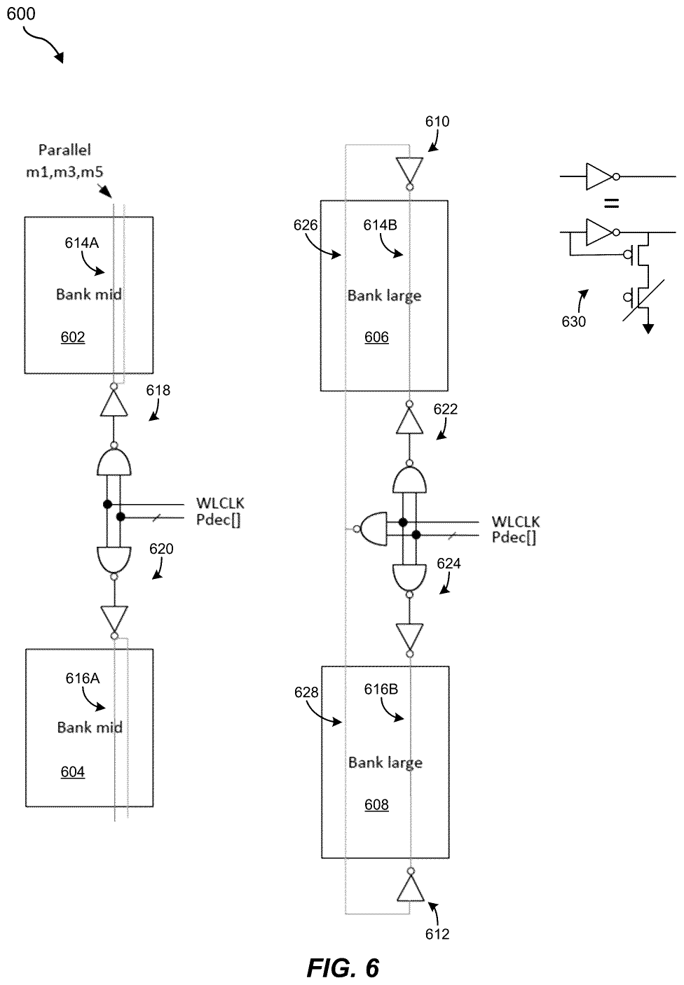

FIG. 6 illustrates a comparison 600 of example memory banks 602, 604, 606, and 608 with and without wordline booster circuitry 610 and 612 (e.g., one or more transistors (e.g., inverters)). For example, example memory banks 602 and 604 can include one or more wordlines 614A and 616A respectively driven by wordline drive circuitry 618 and 620 (e.g., one or more transistors (e.g., inverters), one or more gates (e.g., NAND gates), combinations thereof, etc.). Wordlines 614A and 616A of memory banks 602 and 604 that do not have wordline booster circuitry 610 and 612 can store data in a first capacity (e.g., thirty-five units of data (e.g., bits)).

As shown in FIG. 6, example memory banks 606 and 608 can include one or more wordlines 614B and 616B respectively driven by wordline drive circuitry 622 and 624 (e.g., one or more transistors (e.g., inverters), one or more gates (e.g., NAND gates), combinations thereof, etc.). Wordlines 614B and 616B of memory banks 606 and 608 can also be driven at other ends thereof by wordline booster circuitry 610 and 612, respectively. Memory banks 606 and 608 can also include metal layers 626 and 628 (e.g., higher metal layers) that do not include the wordlines 614B and 616B and that forward a clock signal to wordline booster circuitry 610 and 612, respectively. This clock signal can be gated (e.g., by a NAND gate) instead of inverted by an inverter as previously detailed with reference to FIG. 4. With wordline drive circuitry 622 and 624 driving wordlines 614B and 616B with more circuit elements (e.g., two circuit elements (e.g., NAND gates and inverters)) and the clock signal being processed by less circuit elements (e.g., one circuit element (e.g., a NAND gate)), the forwarded clock signal (e.g., a gated clock signal) can experience less delay compared to a gated and inverted clock signal driving wordlines 614B and 616B. This difference in delay can result in the output signal of the wordline drive circuitry 622 and 624 having the same amplitude and period, but being asynchronous, as shown at 340 in FIG. 3. Wordline booster circuitry 610 and 612 can drive the wordlines 614B and 616B from ends thereof opposite the wordline drive circuitry 622 and 624 and do so under control of the forwarded clock signal, achieving reliable reset of the wordlines 614B and 616B as previously described herein. With wordline booster circuitry 610 and 612, wordlines 614B and 616B can store data in a second capacity (e.g., forty-seven units of data (e.g., bits)) larger than the first capacity of wordlines 614A and 616A. Accordingly, memory banks 604 and 608 can have lengths longer than lengths of memory banks 602 and 604.

As shown in FIG. 6, any or all of wordline drive circuitry 618, 620, 622, and 624 and/or wordline booster circuitry 610 and 612 can have underdrive circuitry 630 implemented in any manner described herein. For example, any or all of wordline drive circuitry 618, 620, 622, and 624 and/or wordline booster circuitry 610 and 612 can include underdrive circuitry 630 connected in parallel with a transistor (e.g., an inverter). This underdrive circuitry 630 can include a first transistor (e.g., a first PMOS transistor) and a second transistor (e.g., a second PMOS transistor) connected in series. Alternatively or additionally, this underdrive circuitry 630 can include a transistor (e.g., a PMOS transistor) having one of its terminals connected between terminals of a pair of transistors (e.g., inverters) that are connected to one another. The transistor can have another of its terminals connected to ground and be set at yet another of its terminals to short the connection between terminals of the pair of transistors at a DC peak value that is less than a voltage of the wordline.

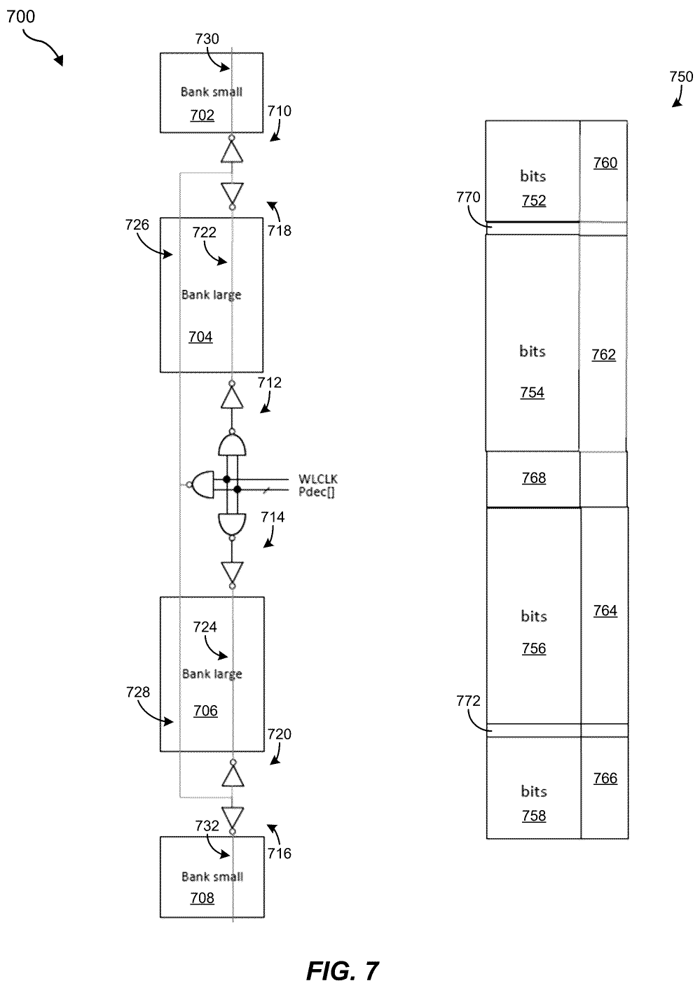

FIG. 7 illustrates a memory device 700 including multiple memory banks 702, 704, 706, and 708 including wordline drive circuitry 710, 712, 714, and 716 and wordline booster circuitry 718 and 720. For example, memory banks 704 and 706 can include one or more wordlines 722 and 724 respectively driven by wordline drive circuitry 712 and 714 (e.g., one or more transistors (e.g., inverters), one or more gates (e.g., NAND gates), combinations thereof, etc.). Wordlines 722 and 724 of memory banks 704 and 706 can also be driven at other ends thereof by wordline booster circuitry 718 and 720, respectively. Memory banks 704 and 706 can also include metal layers 726 and 728 (e.g., higher metal layers) that do not include the wordlines 722 and 724 and that forward a clock signal to wordline booster circuitry 718 and 720, respectively. Thus, memory banks 704 and 706, wordlines 722 and 724, wordline drive circuitry 712 and 714, wordline booster circuitry 718 and 720, and/or metal layers 726 and 728 can have features that are the same or similar to memory banks 606 and 608, wordline booster circuitry 610 and 612, wordlines 614B and 616B, wordline drive circuitry 622 and 624, and/or metal layers 626 and 628 as detailed above with reference to FIG. 6.

As shown in FIG. 7, memory banks 702 and 708 can include wordlines 730 and 732 driven by wordline drive circuitry 710 and 716 respectively. For example, wordline drive circuitry 710 and 716 can receive a clock signal forwarded over metal layers 726 and 728 and drive wordlines 730 and 732 based on the forwarded clock signal. Wordline drive circuitry 710 and 716 can include transistors (e.g., inverters). In contrast to wordlines 722 and 724 of memory banks 704 and 706, wordlines 730 and 732 of memory banks 702 and 708 can be implemented without any wordline booster circuitry. As a result, memory banks 702 and 708 can have a smaller capacity and size compared to memory banks 704 and 706. Additionally, any or all of wordline drive circuitry 710, 712, 714, and 716 and/or wordline booster circuitry 718 and 720 can have underdrive circuitry implemented in any manner described herein.

As shown in FIG. 7, an example memory device 750 can be implemented with bit storage regions 752, 754, 756, and 758 that can contain wordlines. Additionally, example memory device 750 can include input output regions 760, 762, 764, and 766 arranged as shown. Example memory device 750 can also include a decoder region 768 that can contain wordline drive circuitry connected to drive wordlines of bit storage regions 754 and 756. Example memory device 750 can further include regions 770 and 772 that can contain wordline booster circuitry that drives wordlines of bit storage regions 754 and 756 from ends opposite decoder region 768. Example memory device 750 can still further include wordline drive circuitry connected to drive wordlines of bit storage regions 752 and 758.

As shown in FIG. 7, adding additional wordline drive circuitry along with wordline booster circuitry can allow more columns to be added to a memory device (e.g., an SRAM) for performance equivalent to a memory bank having smaller capacity and/or a memory bank having larger capacity with a booster. The resulting memory device can have approximately twice the capacity of a memory bank without wordline booster circuitry. Memory banks 702 and 708 can have less capacity than memory banks 704 and 706. Avoiding addition of boosters to increase the size and capacity of memory banks 702 and 708 can avoid increasing macro height and/or moving beyond a point of beneficial return on area investment.

Benefits achieved with memory device 700 can include faster wordline activation and increased memory density. For example, a wordline can be activated more quickly even at a far end (e.g., opposite wordline drive circuitry). Also, a macro can exhibit approximately twice the input output width (e.g., capacity) compared to a traditional design without wordline booster circuitry. Further, the memory device can amortize the area cost of the decoder and control portions of the memory device across many more bits. For example, a number of data macros (e.. g, L2 cache) supplying a single cacheline can be reduced from eight macros to four macros.

As set forth above, the disclosed systems and methods can boost a wordline. For example, by driving, at a first end of a first memory bank, a first metal layer that includes a wordline of the first memory bank and boosting, based on an output of the first metal layer at a second end of the first memory bank, a voltage of the first metal layer, the disclosed systems and methods can achieve numerous benefits. Example benefits achieved by the disclosed systems and methods can include an increase in the capacity (e.g., length) of a wordline (e.g., a row of a memory bank) without decrease in performance or change of voltage range. Also, increasing the capacity of a memory bank in this way can result in a more efficient use of area in semiconductor devices.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of. ” Finally, for ease of use, the terms “including” and “having” (and their derivatives), as used in the specification and claims, are interchangeable with and have the same meaning as the word “comprising.”

What is claimed is:

1. A device comprising:
a first wordline drive circuit configured to drive, at a first end of a first memory bank, a first metal layer of the first memory bank that includes a wordline; and
a wordline booster circuit configured to boost, based on an output of the first metal layer at a second end of the first memory bank, a voltage of the first metal layer.

2. The device of claim 1, further comprising:
a transistor configured to control the boosting of the voltage based on an output of a second metal layer of the first memory bank.

3. The device of claim 2, further comprising:
a second wordline drive circuit configured to drive, based on the output of the second metal layer, a first metal layer of a second memory bank that includes the wordline.

4. The device of claim 3, wherein the first memory bank has a larger capacity than the second memory bank.

5. The device of claim 2, wherein the second metal layer is a higher metal layer compared to the first metal layer.

6. The device of claim 1, further comprising:
an underdrive circuit configured to decrease an amount by which the voltage of the first metal layer is boosted.

7. The device of claim 1, wherein, during a wordline operation, a duration for which the voltage exceeds ninety-five percent of rail is longer than sixty picoseconds.

8. A system comprising:
a first memory bank including a first metal layer that includes a wordline;
a first wordline drive circuit configured to drive, at a first end of the first memory bank, the first metal layer; and
a first wordline booster circuit configured to boost a voltage of the first metal layer based on an output of the first metal layer at a second end of the first memory bank.

9. The system of claim 8, further comprising:
a transistor configured to control the boosting of the voltage based on an output of a second metal layer of the first memory bank.

10. The system of claim 9, further comprising:
a second wordline drive circuit configured to drive, based on the output of the second metal layer, a first metal layer of a second memory bank, wherein the first metal layer of the second memory bank includes the wordline and the first memory bank has a larger capacity than the second memory bank.

11. The system of claim 9, wherein the second metal layer is a higher metal layer of the first memory bank compared to the first metal layer.

12. The system of claim 8, further comprising:
an underdrive circuit configured to decrease an amount by which the voltage of the first metal layer is boosted.

13. The system of claim 8, wherein, during a wordline operation, a duration for which the voltage exceeds ninety-five percent of rail is longer than sixty picoseconds.

14. A method comprising:
driving, at a first end of a first memory bank, a first metal layer that includes a wordline of the first memory bank; and
boosting, based on an output of the first metal layer at a second end of the first memory bank, a voltage of the first metal layer.

15. The method of claim 14, further comprising:
controlling the boosting of the voltage based on an output of a second metal layer of the first memory bank.

16. The method of claim 15, further comprising:
driving, based on the output of the second metal layer, a first metal layer of a second memory bank that includes the wordline.

17. The method of claim 16, wherein the first memory bank has a larger capacity than the second memory bank.

18. The method of claim 15, wherein the second metal layer is a higher metal layer of the first memory bank compared to the first metal layer.

19. The method of claim 14, further comprising:
employing an underdrive to decrease an amount by which the voltage of the first metal layer is boosted.

20. The method of claim 14, further comprising:
maintaining for longer than sixty picoseconds, during a wordline operation, a duration for which the voltage exceeds ninety-five percent of rail.
